(19) United States
(12) Patent Application Publication
(10) Pub. No.: US 2018/0337331 A1
(43) Pub. Date: Nov. 22, 2018

(54) Two-Dimensional Transition Metal Dichalcogenide Alloys and Electronic Devices Incorporating the Same

(71) Applicant: The Government of the United States of America, as represented by the Secretary of the Navy, Arlington, VA (US)

(72) Inventors: Thomas L. Reinecke, Alexandria, VA (US); Joshua A. Young, Syracuse, NY (US)

(73) Assignee: The Government of the United States of America, as represented by the Secretary of the Navy, Arlington, VA (US)

(21) Appl. No.: 15/974,932

(22) Filed: May 9, 2018

Related U.S. Application Data
(60) Provisional application No. 62/508,403, filed on May 19, 2017.

(51) Int. Cl. H01L 45/00; G01N 27/12; C01B 19/00

(52) U.S. Cl. CPC H01L 45/141; H01L 45/06; H01L 45/1233; H01L 45/1206; C01P 2006/40; C01B 19/007; C01P 2004/20; C01P 2002/54; G01N 27/125

(57) ABSTRACT

New alloys of Group VI transition metal dichalcogenides having the chemical formula MX₂₋ₓX′ₓ, produced using a chalcogen-substitution approach, wherein M is a Group VI transition metal (Cr, Mo, W, or Sg); X is a chalcogen (O, S, Se, Te, or Po); and X′ is a group 15 (N, P, As, Sb, or Bi) or a group 17 (F. Cl, Br, I, or At); and where x ranges from 0 to 2. The stability of different structural phases of such MX₂₋ₓX′ₓ Group VI 2D TMD alloy materials can be tuned via the choice of the chalcogen used. The MX₂₋ₓX′ₓ Group VI 2D TMD alloy materials produced in accordance with the chalcogen-substitution approach of the present invention can be used as components of phase-change based devices such as memory elements, field-effect transistors (FETs), or gas sensors.

### CROSS-REFERENCE

This Application is a Nonprovisional of and claims the benefit of priority under 35 U.S.C. § 119 based on U.S. Provisional Patent Application No. 62/508,403 filed on May 19, 2017. The Provisional Application and all references cited herein are hereby incorporated by reference into the present disclosure in their entirety.

### TECHNICAL FIELD

The present disclosure relates to two-dimensional transition metal dichalcogenide alloys, and particularly to electronic devices incorporating such alloys therein.

### BACKGROUND

Since the isolation of graphene in 2004, quasi two-dimensional (2D) materials have received considerable attention for integration in a wide variety of nanotechnology applications.

In particular, monolayers of the Group VI family of transition metal dichalcogenides (TMDs) are being studied for use in catalysts, nanoelectronics (especially the so-called “valleytronics”); and batteries, owing to the structural flexibility and unique electronic properties granted by their 2D crystal structure. See M. A. Lukowski, et al., Journal of the American Chemical Society 135, 10274 (2013); D. Deng, et al., Nature Nanotechnology 5, 5678 (2014); K. F. Mak, et al., Nature Nanotechnology 7, 494 (2012); K. F. Mak et al., Nature Photonics 10, 216 (2016); and T. Stephenson, et al., Energy and Environmental Science 7, 209 (2014).

These materials, generally referred to as “Group VI transition metal dichalcogenides,” or “Group VI TMDs,” have the general chemical formula MX₂, where M is a Group VI transition metal (Mo or W) and X is a chalcogen (S, Se, or Te), with a single monolayer of such a material consisting of three covalently bonded planes in the order X-M-X. Molecules will adsorb on the surface of these 2D TMD materials. See K. Dolui et al., “Possible doping strategies for MoS2 monolayers: An ab initio study,” Physical Review B 88, 075420 (2013); H. Luo et al., “Adsorption of NO2, NH3 on monolayer MoS2 doped with Al, Si, and P:A first-principles study,” Chemical Physics Letters 643 (2016) 27-33; and J. Zhu et al., “First-principles investigations of metal (V, Nb, Ta)-doped monolayer MoS2: Structural stability, electronic properties and adsorption of gas molecules,” Applied Surface Science 419 (2017) 522-530.

The most common crystal structure of such materials is the H phase, which all Group VI TMDs except one (WTe₂) display under standard conditions. See M. Chhowalla, et al., Nature Chemistry 5, 263 (2013). In this phase, which exhibits an ABA stacking sequence of the X-M-X planes, the TMDs display semiconducting direct band gaps ranging from 1.0 to 1.8 eV.

Changes in the relative arrangement of these planes with respect to one another will alter the crystallographic symmetry, giving rise to several different polymorphs of the material. For example, a relative shift of one chalcogen plane gives rise to the metallic T phase, which can further undergo an alternating contraction and expansion of these planes (via a Peierls-like distortion) to a semimetallic T′ phase. The presence of both the semiconducting H phase and the (semi)metallic T phases in Group VI TMD materials has garnered excitement by researchers, as structural phase change materials exhibiting large changes in conductivity can be harnessed for a variety of technological applications, including new types of rewriteable data storage and memristors for neuromorphic computing. See M. Wuttig et al., Nature Materials 6, 824 (2007); D. Lencer, et al., Nature Materials 7, 972 (2008); and V. K. Sangwan, et al., Nature Nanotechnology 10, 403 (2015).

Although the semiconducting H phase is the most stable in five of the six Group VI TMDs, the (semi)metallic T and T′ phases can be synthesized or induced through a variety of methods, including temperature control, laser patterning, electron beam irradiation, electron charging, treatment with n-butyl lithium, and molecular functionalization of the surface. See M. B. Vellinga, et al., Journal of Solid State Chemistry 2, 299 (1970); D. H. Keum, et al., Nature Physics 11, 482 (2015); J. C. Park, et al., ACS Nano 9, 6548 (2015); S. Cho, et al, Science 349, 625 (2015); Y.-C. Lin, Nature Nanotechnology 9, 391 (2014); G. Gao, et al., J. Phys. Chem. C 119, 13124 (2015); R. Kappera, et al., Nature Materials 13, 1128 (2014); and D. Voiry, et al., Nature Chemistry 7, 45 (2015).

However, the ability to dynamically control the presence of the H and T phases in a single sample remains a significant challenge.

Although there have been several proposals for reversibly switching between the semiconducting and semimetallic states, such as by means of application of mechanical strain, electrostatic charge injection, and transition metal alloying, robust control has yet to be experimentally achieved. See K.-A. N. Duerloo, et al., Nature Communications 5, 4214 (2014); Y. Li, et al, Nature Communications 7, 10671 (2016); C. Zhang, et al., ACS Nano 10, 7370 (2016); L.-Y. Gan, et al., Scientific Reports 4, 6691 (2014); and K.-A. N. Duerloo et al., ACS Nano 10, 289 (2015).

Finding routes to stabilize the T and T′ phases of Group VI 2D TMDs is highly desired, as they display enhanced conductivity, lower contact resistance, and enhanced catalytic activity. Furthermore, it has been proposed that the small energy difference between the semiconducting H and semimetallic T′ phase can lead to reversible metal-insulator transitions, which can then be harnessed for rewriteable data storage and neuromorphic computing.

A wide variety of chemical methods have been previously proposed and used to stabilize the T and T′ phases in 2D MX₂ TMDs, including temperature control, laser patterning, treatment with n-butyl lithium, and molecular functionalization. Methods that have been proposed for controlling the relative stability of the H and T′ phases include alloying of the M transition metal site with a different transition metal to create compounds of the form M₂₋ₓM′ₓX₂ and substituting the X chalcogen anion with a different chalcogen without changing the electron/hole makeup of the material. See Duerloo, supra; see also D.A. Rehn, “Theoretical potential for low energy consumption phase change memory utilizing electrostatically-induced structural phase transitions in 2D materials,” npj Computational Materials 4 2 (2018); and P. Yu et al., “Metal-Semiconductor Phase-Transition in WSe₂₍₁₋ₓ₎Te₂ₓ Monolayer,” Advanced Materials 29, 1603991 (2017).

However, each of these methods has disadvantages, especially in regards to achieving good control over the transition.

### SUMMARY

This summary is intended to introduce, in simplified form, a selection of concepts that are further described in the Detailed Description. This summary is not intended to identify key or essential features of the claimed subject matter, nor is it intended to be used as an aid in determining the scope of the claimed subject matter. Instead, it is merely presented as a brief overview of the subject matter described and claimed herein.

The present invention provides new Group VI two-dimensional transition metal dichalcogenide (2D TMD) material that has controllably changing H and T′ phases.

The materials of the present invention are made using a chalcogen-substitution approach, whereby a portion of the chalcogen is substituted with a group 15 or a group 17 element to produce new Group VI 2D TMD alloys having the chemical formula MX₂₋ₓX′ₓ, where M is a Group VI transition metal (Cr, Mo, W, or Sg); X is a chalcogen (O, S, Se, Te, or Po); and X′ is a group 15 (N, P, As, Sb, or Bi) or a group 17 (F. Cl, Br, I, or At); where x ranges from 0 to 2.

By tuning the choice of the chalcogen substitute used, a material having a desired stability of the H and/or T′ phase can be obtained.

In other aspects of the present invention, the MX₂₋ₓX′ₓ Group VI 2D TMD alloy produced in accordance with the chalcogen-substitution approach of the present invention can be used as a component of devices such as memory elements, field-effect transistors (FETs), and gas sensors.

### BRIEF DESCRIPTION OF THE DRAWINGS

FIGS. 1A and 1B are block schematics illustrating aspects of the crystal structure of the H phase (FIG. 1A) and T′ phase (FIG. 1B) of a conventional Group VI transition metal dichalcogenide (TMD) phase change material.

FIG. 2 is a block schematic illustrating aspects of an exemplary memory element incorporating a MX₂₋ₓX′ₓ Group VI 2D TMD alloy in accordance with the present disclosure.

FIG. 3 is a block schematic illustrating aspects of an exemplary field effect transistor incorporating a MX₂₋ₓX′ₓ Group VI 2D TMD alloy in accordance with the present disclosure.

FIG. 4 is a block schematic illustrating aspects of an exemplary gas sensor incorporating a MX₂₋ₓX′ₓ Group VI 2D TMD alloy in accordance with the present disclosure.

FIGS. 5A and 5B illustrate aspects of gas detection by an exemplary gas sensor according to principles illustrated in FIG. 4.

### DETAILED DESCRIPTION

The aspects and features of the present invention summarized above can be embodied in various forms. The following description shows, by way of illustration, combinations and configurations in which the aspects and features can be put into practice. It is understood that the described aspects, features, and/or embodiments are merely examples, and that one skilled in the art may utilize other aspects, features, and/or embodiments or make structural and functional modifications without departing from the scope of the present disclosure.

Monolayers of conventional Group VI MX₂ 2D TMDs consist of a plane of M atoms covalently bonded to planes of X atoms above and below it, and display high structural flexibility and unique electronic properties owing to their atomic thickness.

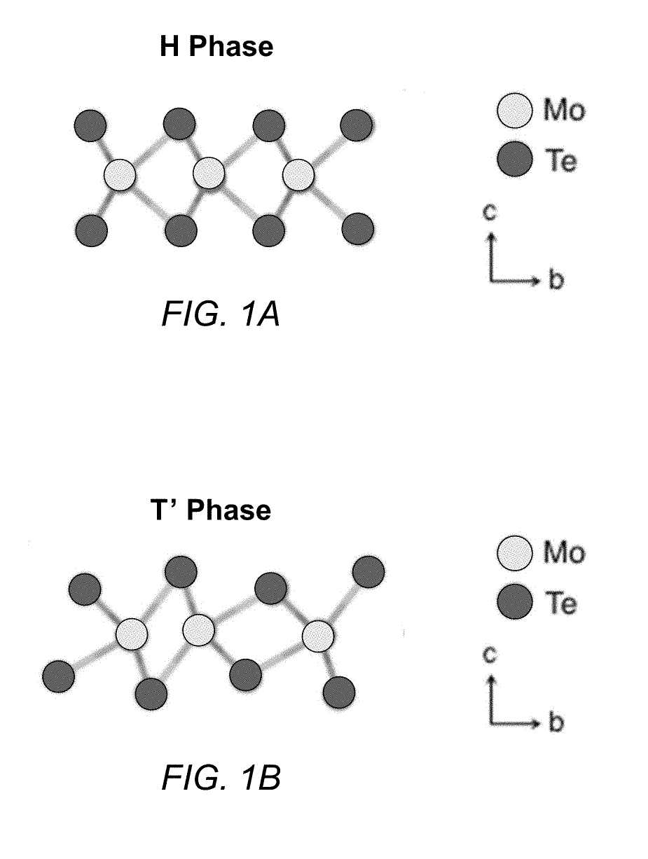

The block schematics in FIGS. 1A and 1B illustrate the crystal structure of certain phases of these materials.

The crystal structure of an exemplary conventional Group VI MX₂ 2D TMD, in which the M atom is Mo and the X atoms are Te, is illustrated in the schematic shown in FIGS. 1A and 1B.

All but one of such Group VI MX₂ 2D TMDs display the so-called H phase shown in FIG. 1A under standard conditions, in which the material has a trigonal prismatic configuration of the transition metal M and a semiconducting band gap ranging from ˜1 to 2 eV.

The planes of the X chalcogen atoms in this structure can readily shift relative to one another. Such a shift will transform the structure to one of several different polymorphs, each having a corresponding set of different electrical, optical, and mechanical properties. For example, a relative shift of one X plane so as to octahedrally coordinate the M atoms results in the metallic T phase. Alternating contractions and expansions then lead to the T′ phase, depicted in FIG. 1B, which has distorted octahedral coordination and exhibits semimetallic behavior.

The H and T′ phase in pure MoTe₂ monolayers are known to be close in energy, and therefore are close in their stability. See Duerloo, supra. The inventors of the present invention have discovered that by combining a 2D TMD with an appropriate species and concentration of another anion, a new 2D TMD alloy having the structure MX₂₋ₓX′ₓ can be formed, where the H and T′ phases exhibited by the original 2D TMD material can be stabilized.

Thus, the present invention provides new Group VI two-dimensional transition metal dichalcogenide (2D TMD) material having controllable H and T′ phases.

The materials of the present invention are made using a chalcogen-substitution approach, whereby a portion of the chalcogen is substituted with a group 15 or a group 17 element to produce new Group VI 2D TMD alloys having the chemical formula MX₂₋ₓX′ₓ, where M is a Group VI transition metal (Cr, Mo, W, or Sg); X is a chalcogen (O, S, Se, Te, or Po); and X′ is a group 15 (N, P, As, Sb, or Bi) ora group 17 (F. Cl, Br, I, or At); where x ranges from 0 to 2.

The chalcogen-substitution approach of the present invention can be used to control the stability of different structural phases of such Group VI TMD materials. Alloying the X chalcogen atoms with certain alternative X′ atoms increases the stability of the T′ phase relative to the H phase. At a specific concentration of X′ atoms (which depends on the X′ species), the energies of the two phases are nearly degenerate. This allows for easily inducing a phase transition through application of a small external perturbation.

The new MX₂₋ₓX′ₓ Group VI 2D TMD alloys in accordance with the present invention can be formed using any one of a variety of different methods.

For example, in some embodiments, MX₂₋ₓX′ₓ Group VI 2D TMD alloys in accordance with the present invention can be synthesized using standard methods such as chemical vapor deposition (CVD). In other embodiments, the MX₂₋ₓX′ₓ Group VI 2D TMD alloys in accordance with the present invention can also be synthesized by implanting pure MX₂ monolayers with the appropriate alloying atom(s) using methods such as hyperthermal ion implantation. One skilled in the art will readily recognize that other suitable methods can be used to synthesize an MX₂₋ₓX′ₓ Group VI 2D TMD alloy in accordance with the present invention, and all such materials formed by any of such methods are deemed to be within the scope and spirit of the present disclosure.

Such new MX₂₋ₓX′ₓ Group VI 2D TMD materials can be integrated into electronic or optoelectronic devices which produce a discernable difference in some property (electronic, optical, etc.) when the material switches between the H and T′ phases upon the application of some external stimulus.

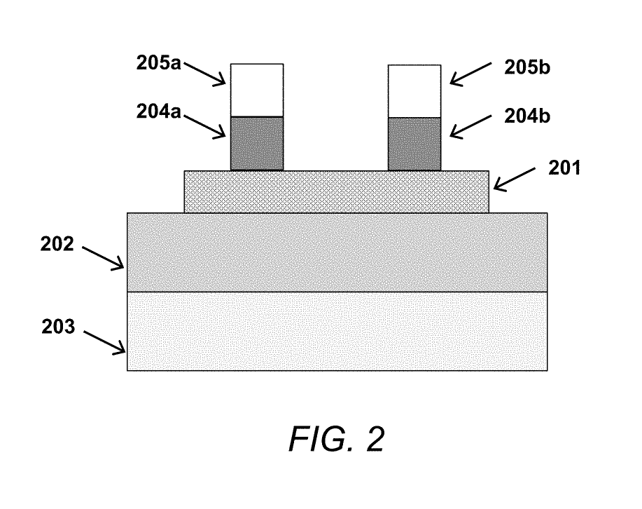

A first exemplary first type of device incorporating an MX₂₋ₓX′ₓ Group VI 2D TMD alloy in accordance with the present disclosure is a memory element. Such a memory element can take any suitable form, with aspects of one exemplary embodiment of such a memory element being illustrated by the block schematic in FIG. 2.

Thus, in the exemplary embodiment illustrated in FIG. 2, a memory element in accordance with the present invention can include an MX₂₋ₓX′ₓ 2D TMD alloy layer 201 disposed on a dielectric layer 202 which in turn is disposed on a substrate 203. The device further includes electrodes 204a/204b connected to MX₂₋ₓX′ₓ 2D TMD alloy layer 201, with each of electrodes 204a and 204b being connected to a corresponding conductive channel 205a/205b. The device can be further connected to other components (not shown) such as a voltage or current source to provide a voltage or current to the device, or a sense amplifier to processes data regarding changes in voltage.

In some in some embodiments, substrate 203 can be formed from a piezoelectric material such as lead zirconium titanate (PZT) or barium titanate. In such embodiments, additional electrodes are placed on substrate 203, wherein an electric field can be applied to expand or contract substrate 203, which in turn applies strain to the MX₂₋ₓX′ₓ 2D TMD alloy layer 201. The degree of strain induced into the MX₂₋ₓX′ₓ 2D TMD alloy layer 201 is tunable by controlling the strength of the applied electric field.

In other embodiments, substrate 203 is formed from a material that has a different thermal expansion coefficient than does dielectric layer 202. For example, if dielectric layer 202 is SiO₂, substrate 203 can be another dielectric with a different thermal expansion coefficient, such as Si. In such a case, an applied change in the temperature of substrate 203 would induce a strain to MX₂₋ₓX′ₓ 2D TMD alloy layer 201, with the degree of induced strain being tunable by controlling the degree of the applied temperature change. In such embodiments, the temperature can be changed by any suitable means, such as connecting the substrate to a heater that controllably applies and removes heat, applying a source of cooling to the substrate, or configuring the substrate to be heated by Joule heating; all of these and other such configurations are deemed to be within the scope of the present disclosure.

In either case, the MX₂₋ₓX′ₓ 2D TMD alloy 201 is used to store information in the memory device, with one of the two H or T′ phases corresponding to one of the binary “0” or “1” states and the other phase corresponding to the other state, depending on the electrical or optical properties of the MX₂₋ₓX′ₓ 2D TMD material used. For example, the conductivity of the material is lower in the H phase and so the H phase can correspond to the “0” state, while the higher conductivity T′ phase can correspond to the “1” state, though the opposite case, where the T′ phase corresponds to the “0” state and the H phase corresponds to the “1” state can also be present.

The information stored in the MX₂₋ₓX′ₓ 2D TMD alloy can be read by measuring its conductivity, which, as noted above, is lower in the H phase and higher in T′ phase. This measurement is done by applying a read current through electrodes 204a/204b, which are connected to an electrical source through conductive channels 205a/b, with the resulting read voltage compared against a reference voltage. A low read voltage indicates that the alloy is in a low conductivity phase (“0” state), while a high read voltage indicates the alloy is in a high conductivity phase (“1” state).

In the exemplary memory device illustrated in FIG. 2, the phase of the MX₂₋ₓX′ₓ 2D TMD alloy layer 201 can be converted from the lower conducting H phase (a state of “0”) to the higher conducting T′ phase (a state of “1”) and back again via the application and removal of a strain in the 2D TMD material. As noted above, in some embodiments, the strain can be electrically induced, e.g., from a voltage applied to a piezoelectric substrate 203, while in other embodiments it can be thermally induced, e.g., by a change in temperature of substrate 203 from an application of heat or cooling from a heating or cooling element (not shown) coupled to the substrate. This change in the phase of the alloy resulting from the strain in the device produces a change from a “0” state to a “1” state which results in a “writing” of information into the device's memory.

Thus, in the exemplary embodiment illustrated in FIG. 2, electrodes 204a/204b apply an appropriate current to MX₂₋ₓX′ₓ 2D TMD alloy layer 201 by means of conductive channels 205a/205b, and the resulting voltage across the alloy layer 201 (“read” voltage) can be compared to a known reference voltage (not shown). A low “read” voltage indicates that the alloy is in a low conductivity phase (H phase, or “0” state), while a high read voltage indicates the alloy is in a high conductivity phase (T′ phase, or “1” state). This measurement permits the “reading” of the information stored in the device's memory.

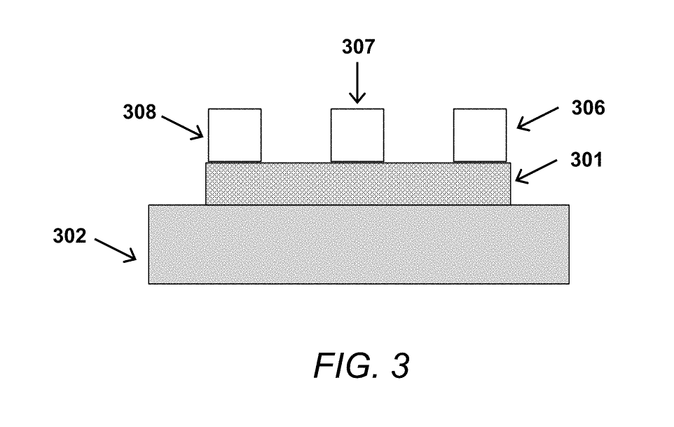

A second exemplary type of device that can incorporate an MX₂₋ₓX′ₓ Group VI 2D TMD alloy in accordance with the present disclosure is a field effect transistor (FET). Aspects of an exemplary embodiment of such a FET are illustrated by the block schematic shown in FIG. 3. However, as with the memory element described above, one skilled in the art will readily recognize that a FET incorporating a MX₂₋ₓX′ₓ Group VI 2D TMD alloy in accordance with this aspect of the present invention can take any suitable form, and all such alternative embodiments and forms of such a FET are deemed to be within the scope and spirit of the present disclosure.

Thus, as illustrated in FIG. 3, an exemplary FET device in accordance with one or more aspects of the present invention includes a MX₂₋ₓX′ₓ Group VI 2D TMD alloy layer 301 as described above disposed on a dielectric layer 302. The device further includes source 306, gate 307, and drain 308 electrodes well known in the art contacting the MX₂₋ₓX′ₓ Group VI 2D TMD material.

In accordance with the present invention, a change from the H to the T′ phase in the MX₂₋ₓX′ₓ Group VI 2D TMD material can be induced by means of carrier injection through gate electrode 307, where the injection of either electrons or holes stabilizes the T′ phase over the H phase. The transition from the H to T′ phase results in change from a state of low conductivity to high conductivity, and thus a change in the FET from an OFF to ON state, thereby controlling a flow of current through the device.

A third type of device that can incorporate the MX₂₋ₓX′ₓ Group VI 2D TMD alloys in accordance with the present invention are gas sensors in which changes in the conductivity of the alloys allow for the sensing of different atoms or molecules.

Unlike the memory device and transistor described above with respect to FIGS. 2 and 3, a gas sensor in accordance with this aspect of the present invention does not rely on phase changes. Instead, it relies on changes in the conductivity of the MX₂₋ₓX′ₓ Group VI 2D TMD within the single H, T, or T′ phase upon the adsorption of gas molecules onto the surface of the material.

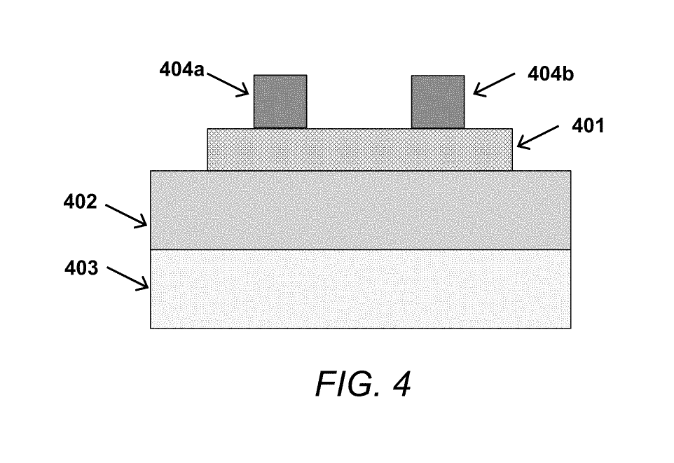

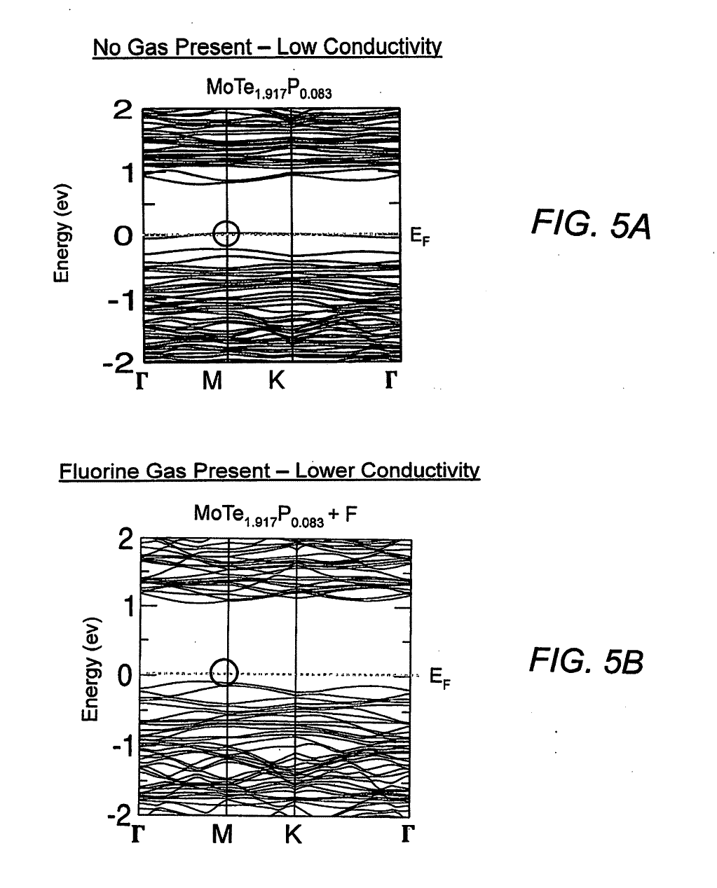

FIG. 4 and FIGS. 5A-5B illustrate aspects of such a gas sensor in accordance with this aspect of the present invention.

FIG. 4 illustrates an exemplary embodiment of such a gas sensor. In the embodiment illustrated in FIG. 4, a layer 401 of a MX₂₋ₓX′ₓ Group VI 2D TMD alloy material as described above is disposed on a dielectric layer 402 (which can be SiO₂ or any other suitable material), which in turn can optionally be situated on a substrate 403, e.g., a layer of p-doped Si. Source and drain contacts 404a/404b are connected to the 2D TMD phase change material layer, and measure its conductivity.

If no gas molecules have adsorbed onto the surface, the material will exhibit a first conductivity, whereas if gas molecules have adsorbed, the material will exhibit a second conductivity, which can be lower or higher than the first conductivity. This change in conductivity of MX₂₋ₓX′ₓ Group VI 2D TMD alloy layer 401 can be measured by a change in the current traveling through the source and drain contacts and thus, the device can serve as a detector of gas incident on the material surface.

FIGS. 5A and 5B illustrate aspects of an exemplary case of a gas sensor in accordance with the present disclosure. In the exemplary case illustrated in FIGS. 5A and 5B, calculations were made regarding the electronic properties of an exemplary gas sensor comprising MoTe_{1.917}P_{0.083} with and without fluorine (F) gas adsorbates present.

As can be seen from the plot in FIG. 5A, when no gas molecules were present, the MoTe_{1.917}P_{0.083} exhibited a small number of states above the Fermi energy EF (which is set to 0 in the FIGURES), as indicated by the energy band within the circle, and thus the material is in the first conductivity state, i.e., a “conducting” state. In contrast, as illustrated in FIG. 5B, when fluorine gas is on the surface (MoTe_{1.917}P_{0.083}+F), the valence band is below the Fermi level EF, and so the material is in a second, conductivity state, this one a “less conducting” state than is the case where no fluorine is present.

Advantages and New Features

The general architectures of the electronic devices we propose here are well known. Indeed, entire segments of the electronics industry are based on devices of this type. See, e.g., Z. Yuan et al., “Interfacing 2D Semiconductors with Functional Oxides: Fundamentals, Properties, and Applications,” Crystals 2017, 7, 265; M. Chhowalla et al., “Two-dimensional semiconductors for transistors,” Nature Reviews Materials 1, 16052 (2016); and R. Samnakay, “Selective chemical vapor sensing with few-layer MoS2 thin-film transistors: Comparison with graphene devices,” Appl. Phys. Lett. 106, 023115 (2015).

The novelty in this work is the creation and use of the MX₂₋ₓX′ₓ Group VI 2D TMD alloys, where the X′ atoms substitute for the X atoms in conventional MX₂ TMDs to create stable H and T′ phases. Although there have been several attempts to deterministically stabilize a desired phase, none have relied on the X′ chalcogen-substitution alloying of the present invention. Thus, the present invention provides a new way to control the stability of either the H or T′ phase through selection of appropriate X′ alloying species.

In addition, by choosing the appropriate species and concentration of the X′ element, the energy difference between the H and T′ phases can be made to be very close. This provides many new materials with which to dynamically control the H to T′ phase transition in devices that include the MX₂₋ₓX′ₓ Group VI 2D TMD alloys in accordance with the present invention, such as the memory element, transistor, and sensor described above. Such materials can provide a level of dynamical control over phase change-related properties in such devices that heretofore have not been achieved.

Alternatives

This method extends to alloys of all members of the Group VI MX₂ transition metal dichalcogenide family, including MoS₂, MoSe₂, MoTe₂, WS₂, WSe₂, and WTe₂, as well as additional alloys having more than one Group VI material, i.e., alloys having the form M_{y}M′_{1-y}X₂₋ₓX′ₓ. It also includes devices that use any number of layers of a MX₂₋ₓX′ₓ Group VI 2D TMD alloy in accordance with the present invention (i.e., monolayer, bilayer, etc.).

Although particular embodiments, aspects, and features have been described and illustrated, one skilled in the art would readily appreciate that the invention described herein is not limited to only those embodiments, aspects, and features but also contemplates any and all modifications and alternative embodiments that are within the spirit and scope of the underlying invention described and claimed herein. The present application contemplates any and all modifications within the spirit and scope of the underlying invention described and claimed herein, and all such modifications and alternative embodiments are deemed to be within the scope and spirit of the present disclosure.

What is claimed is:

1. A two-dimensional transition metal dichalgoenide (2D TMD) material having the formula MX₂₋ₓX′ₓ, wherein
M is a Group VI transition metal comprising Cr, Mo, W, or Sg;
X is a chalcogen comprising O, S, Se, Te, or Po;
X′ is a group 15 element comprising N, P, As, Sb or Bi or is a group 17 element comprising F, Cl, Br, I, or At; and
x ranges from 0 to 2.

2. The 2D TMD material according to claim 1, wherein M comprises a first Group VI transition metal comprising one of Cr, Mo, W, or Sg and a second Group transition metal comprising one of, wherein the material has the formula M_{y}M′_{1-y}X₂₋ₓX′ₓ, where y ranges from 0 to 1

3. A memory element, comprising:
a substrate;
a dielectric material layer disposed on the substrate;
a two-dimensional transition metal dichalcogenide (2D TMD) alloy layer disposed on the dielectric layer, the 2D TMD alloy layer being a MX₂₋ₓX′ₓ Group VI 2D TMD alloy layer, where
M is a Group VI transition metal comprising Cr, Mo, W, or Sg;
X is a chalcogen comprising O, S, Se, Te, or Po;
X′ is a group 15 element comprising N, P, As, Sb or Bi or is a group 17 element comprising F, Cl, Br, I, or At; and
x ranges from 0 to 2;
the memory element further comprising:
at least one electrode connected to the MX₂₋ₓX′ₓ Group VI 2D TMD alloy layer, each of the electrodes being connected to an electrical source via a corresponding conductive channel; and
means for inducing a strain to the MX₂₋ₓX′ₓ Group VI 2D TMD alloy layer;
wherein the applied strain induces a phase change in the MX₂₋ₓX′ₓ Group VI 2D TMD alloy layer from a low conductivity H phase to a high conductivity T′ phase;
wherein the H phase corresponds to a “0” state in the memory device and the T′ phase corresponds to a “1” state; and
wherein information can be written into the memory device when the MX₂₋ₓX′ₓ Group VI 2D TMD alloy layer is in H phase and read out of the memory device when the MX₂₋ₓX′ₓ Group VI 2D TMD alloy layer is in the T′ phase.

4. The memory element according to claim 3, wherein the substrate comprises a piezoelectric material, the memory element further comprising at least one electrode connected to the substrate, the electrode being configured to apply an electric field to the substrate so as to expand or contract the substrate, thereby inducing the strain in the MX₂₋ₓX′ₓ Group VI 2D TMD alloy layer,
a degree of the induced strain being tunable by tuning a strength of the applied electric field.

5. The memory element according to claim 3, wherein the substrate comprises a material having a thermal expansion coefficient different from a thermal expansion coefficient of the dielectric material layer, the memory element further comprising a heating/cooling element coupled to the substrate, the heating/cooling element being configured to change the temperature of the substrate so as to expand or contract the substrate, thereby inducing the strain in the MX₂₋ₓX′ₓ Group VI 2D TMD alloy layer,
a degree of the induced strain being tunable by tuning a temperature applied by the heating/cooling element.

6. A field effect transistor, comprising:
a dielectric material layer disposed on a substrate;
a two-dimensional transition metal dichalcogenide (2D TMD) alloy layer disposed on the dielectric layer, the 2D TMD alloy layer being a MX₂₋ₓX′ₓ Group VI 2D TMD alloy layer, where
M is a Group VI transition metal comprising Cr, Mo, W, or Sg;
X is a chalcogen comprising O, S, Se, Te, or Po;
X′ is a group 15 element comprising N, P, As, Sb or Bi or is a group 17 element comprising F, Cl, Br, I, or At; and
x ranges from 0 to 2;
the field effect transistor further comprising source, gate, and drain electrodes connected to the MX₂₋ₓX′ₓ Group VI 2D TMD alloy layer;
wherein an injection of carriers into the MX₂₋ₓX′ₓ Group VI 2D TMD alloy layer via the gate induces a phase change in the MX₂₋ₓX′ₓ Group VI 2D TMD alloy layer from a low conductivity H phase to a high conductivity T′ phase;
wherein the transistor is in the nonconducting “OFF” state when the MX₂₋ₓX′ₓ Group VI 2D TMD alloy layer is in the H phase and is in the conducting “ON” state when the MX₂₋ₓX′ₓ Group VI 2D TMD alloy layer is in the T′ phase.

7. A gas sensor, comprising:
a dielectric material layer disposed on a substrate;
a two-dimensional transition metal dichalcogenide (2D TMD) alloy layer disposed on the dielectric layer, the 2D TMD alloy layer being a MX₂₋ₓX′ₓ Group VI 2D TMD alloy layer, where
M is a Group VI transition metal comprising Cr, Mo, W, or Sg;
X is a chalcogen comprising O, S, Se, Te, or Po;
X′ is a group 15 element comprising N, P, As, Sb or Bi or is a group 17 element comprising F, Cl, Br, I, or At; and
x ranges from 0 to 2;
the gas sensor further comprising source and drain electrodes connected to the MX₂₋ₓX′ₓ Group VI 2D TMD alloy layer;
wherein the MX₂₋ₓX′ₓ Group VI 2D TMD alloy exhibits a first conductivity when no gas is present on a surface of the MX₂₋ₓX′ₓ Group VI 2D TMD alloy and a second conductivity when gas is present on its surface; and
wherein a presence of a gas incident on the MX₂₋ₓX′ₓ Group VI 2D TMD alloy can be detected by a change in current traveling through the source and drain electrodes.
